(19) United States
(12) Patent Application Publication
(10) Pub. No.: US 2010/0008170 A1
(43) Pub. Date: Jan. 14, 2010

(54) Semiconductor tester and testing method of semiconductor memory

(76) Inventors: Shinya Sato, Tokyo-To (JP); Makoto Tabata, Tokyo-To (JP)

Correspondence Address: BIRCH STEWART KOLASCH & BIRCH, PO BOX 747, FALLS CHURCH, VA, 22040-0747, US

(21) Appl. No.: 11/919,585

(22) PCT Filed: Apr. 20, 2007
(86) PCT No.: PCT/JP2007/058604

§ 371 Date: Oct. 30, 2007

(51) Int. Cl. G11C 29/00; G06F 19/00

(52) U.S. Cl. 365/201; 702/124

(57) ABSTRACT

The disclosure concerns a semiconductor tester for testing a memory under test. The semiconductor tester comprises a pattern generator generating address information on the pages and generating a test pattern; a waveform shaper shaping the test pattern and outputting a test signal based on the shaped test pattern to the memory cells in the page identified by the address information; a comparator comparing a result signal output from the memory under test receiving the test signal with an expectation value; and a bad block memory storing information on a bad block in the memory under test in advance, when the page identified by the address information is included in the bad block, the bad block memory outputting a bad signal used to skip from the address information on the page included in the bad block to the address information on the page included in a next block under test.

### BACKGROUND OF THE INVENTION

1. Field of the Invention

The present invention relates to a semiconductor tester, for example, a semiconductor tester testing a data storage memory, e.g., a NAND flash memory, rewritable in units of the memory, i.e., blocks.

2. Related Art

A semiconductor memory tester includes a timing generator, a pattern generator, a waveform shaper, and a logic comparator. The timing generator generates a periodic clock and a delay clock based on timing data designated by a timing set signal (hereinafter, “TS signal”) output from the pattern generator. The pattern generator outputs test pattern data to be supplied to a MUT (memory under test) according to the periodic clock from the timing generator, to the waveform shaper. In response to the test pattern data, the waveform shaper shapes a waveform of timing necessary for a test using the delay clock, and applies the shaped test signal to the MUT. A result signal output from the MUT is supplied to the logic comparator. The logic comparator compares expectation value data from the pattern generator with the result signal output from the MUT, and determines whether the MUT is good or bad based on a comparison result that the expectation value is matched or unmatched with the result signal.

A conventional semiconductor memory tester includes a BBM (bad block memory) that stores therein bad block information. The bad block information is address information on a block that has been already determined as a bad block in a wafer process. Accordingly, the BBM is a memory having a sufficient capacity to store at least the number of block addresses. The BBM transmits an instruction to prohibit a write operation for writing data to the MUT to the waveform shaper according to the bad block information, and also transmits an instruction to prohibit a comparison operation using the result signal so as to exclude the bad block from blocks under test. This makes it unnecessary to write data to memory cells in the bad block and to compare the expectation value with each of the result signals from the memory cells in the bad block. As a result, memory test time can be shortened.

However, accesses to respective pages in the bad block still continue despite prohibition of both writing of data to the bad block and comparison using the result signals. Although access time of each of the accesses is shorter than normal test time for a good block, it disadvantageously takes quite lots of time to perform all the accesses because the respective pages in the bad block are accessed.

Because, recently, the capacity of the NAND flash memory, in particular, has doubled annually, the test time tends to be lengthened, accordingly. Therefore, the unnecessary access to the bad block disadvantageously pushes up test cost.

It is an object of the present invention to provide a semiconductor tester capable of solving the conventional disadvantages, saving time for access to a bad block, and shortening test time.

### SUMMARY OF THE INVENTION

A semiconductor tester according to an embodiment of the present invention for testing a memory under test including a block function capable of rewriting data in units of blocks including a plurality of pages, the plurality of pages including a plurality of bits stored in a plurality of memory cells, the semiconductor tester comprising: a pattern generator generating address information on the pages and generating a test pattern; a waveform shaper shaping the test pattern and outputting a test signal based on the shaped test pattern to the memory cells in the page identified by the address information; a comparator comparing a result signal output from the memory under test receiving the test signal with an expectation value; and a bad block memory storing information on a bad block in the memory under test in advance, when the page identified by the address information is included in the bad block, the bad block memory outputting a bad signal used to skip from the address information on the page included in the bad block to the address information on the page included in a next block under test.

The bad block memory outputs an instruction to prohibit an output operation for outputting the test signal to the waveform shaper and outputs an instruction to prohibit a comparison operation for comparing the result signal with the expectation value to the comparator, when the memory cells identified by the address information are included in the bad block.

The semiconductor tester further comprises a conditional branching instruction changer receiving a conditional branching instruction to change a generation pattern of the address information from the pattern generator, the conditional branching instruction changer changing the conditional branching instruction based on the bad signal.

The bad signal is output to the pattern generator as a conditional branching instruction to change a generation pattern of the address information, the generation pattern generated by the pattern generator.

The semiconductor tester further comprises

a matching detector comparing the result signal output from the memory under test with the expectation value and outputting a match signal indicating whether the result signal is matched or unmatched with the expectation value, wherein

the conditional branching instruction changer includes a multiplexer selecting one of the bad signal output from the bad block memory and the match signal output from the matching detector as the conditional branching instruction.

A method of testing a memory under test using a semiconductor tester according to an embodiment of the present invention, the memory under test including a block function capable of rewriting data in units of blocks including a plurality of pages, the plurality of pages being a plurality of bits stored in a plurality of memory cells,

the semiconductor tester includes: a pattern generator generating address information on the pages and generating a test pattern; a waveform shaper shaping the test pattern and outputting a test signal based on the shaped test pattern to the memory cells in the respective pages identified by the address information; a comparator comparing a result signal output from the memory under test receiving the test signal with an expectation value; and a bad block memory storing information on a bad block in the memory under test in advance, and wherein

the method comprises: outputting a bad signal used to skip from the address information on the pages included in the bad block to the address information on the pages included in a next block under test, when the pages identified by the address information are included in the bad block.

The bad block memory outputs an instruction to prohibit an output operation for outputting the test signal to the waveform shaper and outputs an instruction to prohibit a comparison operation for comparing the result signal with the expectation value to the comparator in the step of outputting the bad signal.

The method further comprises outputting the bad signal to the pattern generator as a conditional branching instruction to change a generation pattern of the address information, the generation pattern generated by the pattern generator.

The semiconductor tester according to the present invention can save the time for access to the bad block and shorten the test time.

### BRIEF DESCRIPTION OF THE DRAWINGS

FIG. 1 is a schematic block diagram showing a semiconductor memory tester 100 according to an embodiment of the present invention;

FIG. 2 shows the internal configuration of the flash memory in a blank state; and

FIG. 3 is a flowchart showing an operation performed by the tester 100 according to the embodiment.

### DETAILED DESCRIPTION OF THE INVENTION

Embodiments of the present invention will be explained below with reference to the accompanying drawings. The present invention is not limited to the embodiments.

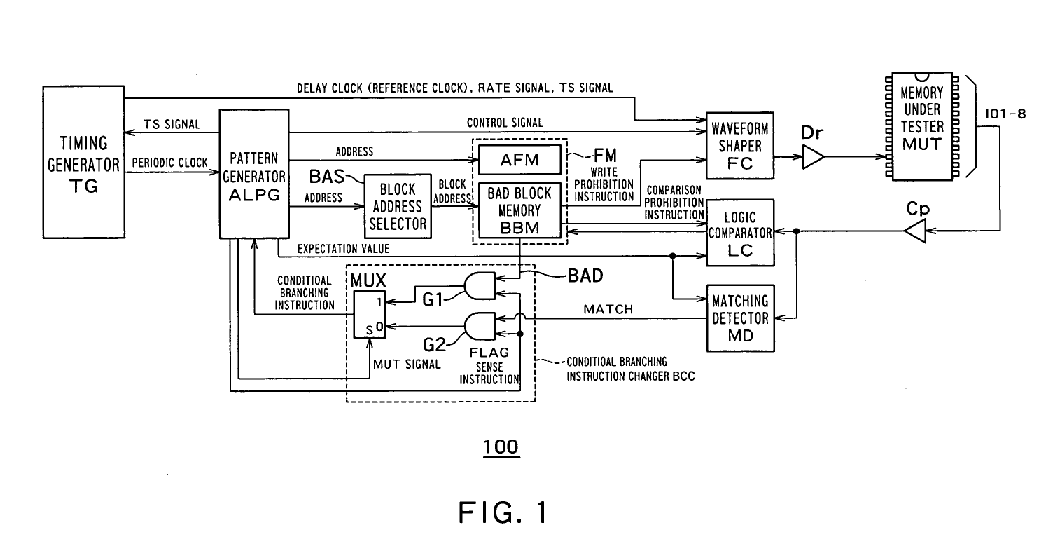

FIG. 1 is a schematic block diagram showing a semiconductor memory tester 100 (hereinafter, “tester 100”) according to an embodiment of the present invention. The tester 100 includes a timing generator TG, a pattern generator ALPG, a waveform shaper FC, a logic comparator LC, a fail bit memory FM, a block address selector BAS, a matching detector MD, and a conditional branching instruction changer BCC.

The pattern generator ALPG outputs a TS signal to the timing generator TG. In response to the TS signal, the timing generator TG generates timing edges of various many channels specified based on a timing set described in a device test program. The timing generator TG thereby generates a periodic clock and a delay clock. The pattern generator ALPG generates address information on memory cells in a memory under test (hereinafter, “MUT”), and outputs test pattern data to be supplied to the memory cells according to the periodic clock, to the waveform shaper FC.

The waveform shaper FC shapes test pattern data to a waveform of timing necessary for a test based on the delay clock, and applies the shaped test pattern to the MUT according to the address information.

In response to a test signal, the MUT writes predetermined data to the memory cells therein and reads the data from the memory cells. A signal read from the MUT is supplied to the logic comparator LC. The logic comparator LC compares expectation value data from the pattern generator ALPG with a result signal output from the MUT, thereby determining whether the MUT is good or bad based on a comparison result that the expectation value is matched or unmatched with the result signal. The comparison result of the logic comparator LC is stored in a failure analysis memory AFM within the fail bit memory FM for every address. The failure analysis memory AFM is configured to be able to store good/bad determination results of all bits of the MUT. The failure analysis memory AFM is used for a processing of determining whether the MUT can be relieved based on the number of bad cells or the number of bad blocks in the MUT.

In response to page address information from the pattern generator ALPG, the block address selector BAS outputs a block address including a page under test identified by the page address information. The bad block memory BBM stores therein data indicating good/bad determination for every block in the MUT. The data indicating the good/bad determination for every block is, for example, one-bit data. Therefore, it suffices to constitute the bad block memory by a memory having a storage capacity to store data as much as the number of blocks or more in the MUT and having a capacity equal to or larger than one bit for every block address.

The bad block memory BBM outputs a bad flag signal BAD. The bad flag signal BAD indicates a bad block by one of binary data “0” and “1” and a good block by the other binary data. The bad flag signal BAD is used to change a test pattern generation sequence. For example, if a block identified by the block address is a bad block, the bad flag signal BAD is used to skip from the block address of the bad block to an address of a block next to the bad block. The bad block memory BBM outputs a write prohibition instruction to prohibit a test data write operation to the waveform shaper FC and a comparison prohibition instruction to prohibit comparison of the result signal with an expectation value to the logic comparator LC, simultaneously with the bad flag signal BAD.

The matching detector MD is configured to detect whether the result signal from the MUT is matched or unmatched with the expectation value, and to output a match flag signal MATCH. The match flag signal MATCH is a signal indicating whether the result signal is matched or unmatched with the expectation value. The match flag signal MATCH can indicate a bad block by one of binary data “0” and “1” and a good block by the other binary data based on data in a block in a blank state. The match flag signal MATCH is used to change the test pattern generation sequence similarly to the bad flag signal BAD.

The conditional branching instruction changer BCC includes AND gates G1 and G2 and a multiplexer MUX. The AND gate G1 performs an AND operation between the bad flag signal BAD from the bad block memory BBM and a FLAG sense instruction from the pattern generator ALPG, and outputs a result of the AND operation to the multiplexer MUX. The AND gate G2 performs an AND operation between the match flag signal MATCH from the matching detector MD and the FLAG sense instruction, and outputs a result of the AND operation to the multiplexer MUX. The multiplexer MUX is configured to receive a flag sense selection signal MUT from the pattern generator ALPG, and to select one of the bad signal BAD and the match signal MATCH based on the flag sense selection signal MUT. The signal selected by the multiplexer MUX is output to the pattern generator ALPG as a conditional branching instruction. In this manner, the multiplexer MUX can select one of the bad signal BAD and the match signal MATCH as the conditional branching instruction in every test cycle.

The pattern generator ALPG changes the test pattern generation sequence based on the conditional branching instruction. It is assumed, for example, that if the block under test is a good block, the bad flag signal BAD is data “0” or the match flag signal MATCH is data “1”. In this case, the pattern generator ALPG advances a test sequence of the block (NOP instruction).

On the other hand, it is assumed, for example, that if the block under test is a bad block, the bad flag signal BAD is data “1” or the match flag signal MATCH is data “0”. In this case, the pattern generator ALPG does not execute the test sequence of the block but skips from the block address of the bad block to an address of a page in a block next to the bad block (JUMP instruction).

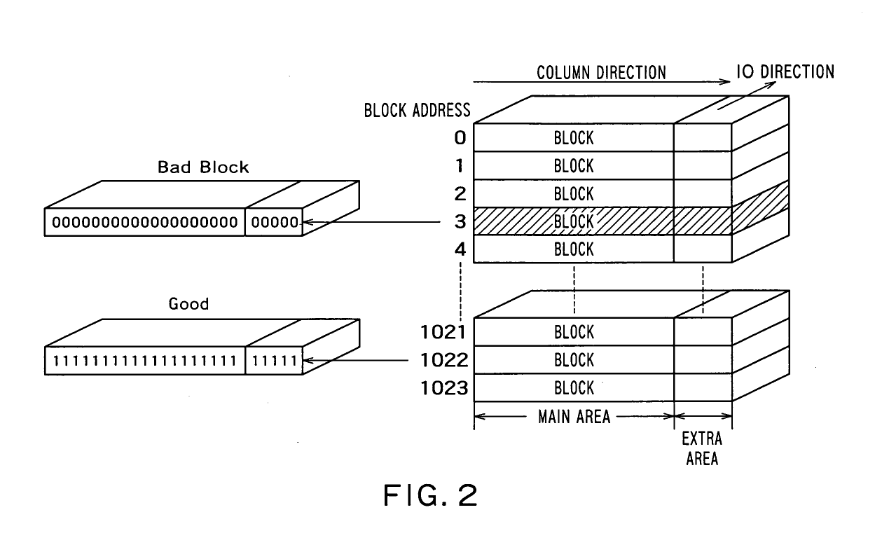

FIG. 2 is a schematic diagram showing an internal configuration of a data storage flash memory (hereinafter, “flash memory”). The flash memory is configured to include a plurality of blocks each constituted by a plurality of pages. Each of the pages is constituted by a plurality of bits stored in a plurality of memory cells, respectively. During a data write operation or a data read operation, data is transferred between a page register provided in the flash memory and a memory cell array in units of pages. A data erasing/rewriting operation is performed in units of blocks.

A data storage memory is easier to structurally integrate than a code storage memory typified by a NOR flash memory. Due to this, the data storage memory is relatively inexpensive per bit.

However, the data storage memory is inferior to the code storage memory in reliability. Due to this, in a test on the data storage memory, it is determined that the data storage memory is good only if all memory cells can operate. As a result, yield is considerably deteriorated. For example, if 98% of blocks in a chip are good blocks, the chip is determined as a good chip. For this reason, the data storage memory is required to be marked to indicate whether memory cells are usable at the time of shipping of chips. Determination as to whether memory cells are usable is managed in units of blocks. An unusable block is referred to as “bad block” whereas a usable block is referred to as “good block”. At the time of shipping of memories, data “0” is written to each bad block and data “1” is written to each good block. This state is referred to as “blank state”.

FIG. 2 shows the internal configuration of the flash memory in a blank state. The number of blocks in the flash memory according to the embodiment is 1024 and the blocks can be identified by block addresses 0 to 1023, respectively. For example, a block identified by a block address 3 is a bad block and data “0” is written to memory cells on all pages in this block. A block identified by a block address 1022 is a good block and data “1” is written to memory cells on all pages in this block.

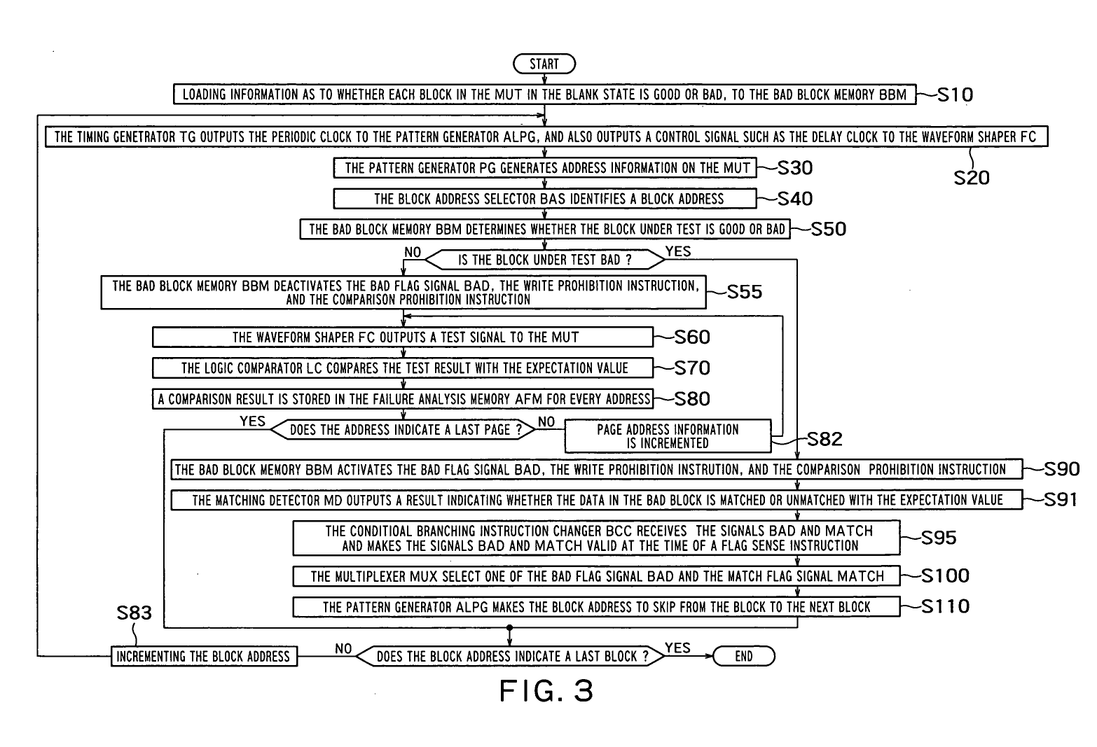

FIG. 3 is a flowchart showing an operation performed by the tester 100 according to the embodiment. The tester 100 performs a test on the memory in the blank state shown in FIG. 2. First, information as to whether each block in the MUT in the blank state is good or bad is loaded to the bad block memory BBM (S10). The bad block memory BBM stores therein the good/bad information on each block. For example, since the block identified by the block address 3 is a bad block, the bad block memory BBM sets bits corresponding to the block address 3 to data “0”, respectively. Since the block identified by the block address 1022 is a good block, the bad block memory BBM sets bits corresponding to the block address 1022 to data “1”, respectively.

Next, a test is started on the MUT. In response to the TS signal, the timing generator TG outputs the periodic clock to the pattern generator ALPG, and also outputs a control signal such as the delay clock to the waveform shaper FC (S20). The pattern generator ALPG generates address information on the MUT and outputs the address information to the fail bit memory FM and to the block address selector BAS (S30). The block address selector BAS identifies a block address including those of memory cells under test identified by the address information from the pattern generator ALPG, and outputs the block address to the bad block memory BBM (S40). The bad block memory BBM determines whether the block under test identified by the block address output from the block address selector BAS is good or bad (S50).

If the block under test is a good block, the bad block memory BBM deactivates the bad flag signal BAD, the write prohibition instruction, and the comparison prohibition instruction (S55). By doing so, the waveform shaper FC outputs a test signal to the MUT (S60). The logic comparator LC receives a test result from the MUT and compares the test result with the expectation value (S70). Good/bad data as a comparison result is stored in the failure analysis memory AFM for every address (S80).

If the address does not indicate a last page, then page address information is incremented (S82), and the test (S60 to S80) is repeated. In this manner, the steps S55 to S80 are executed to all pages in the block under test.

If the address indicates the last page, the pattern generator ALPG increments the block address after end of reading of data from the last page (S83). As a consequence, the tester 100 performs a test on a next block.

If the block under test is a bad block, the bad block memory BBM activates the bad flag signal BAD, the write prohibition instruction, and the comparison prohibition instruction (S90). By doing so, the waveform shaper FC stops outputting the test signal, and the logic comparator LC stops the comparison operation with respect to the data read from the bad block. The matching detector MD detects whether the data read from the bad block is matched or unmatched with the expectation value, and outputs a detection result (S91). At this moment, the data in the bad block is all “0” as already stated with reference to FIG. 2. Due to this, if the expectation value is “0”, the matching detector MD outputs the signal (e.g., “0”) indicating that the data read from the bad block is matched with the expectation value. If the expectation value is “1”, the matching detector MD outputs the signal (e.g., “1”) indicating that the data read from the bad block is unmatched with the expectation value. Namely, it is possible to detect whether or not the block under test is a bad block not only by the bad flag signal BAD but also by the match flag signal MATCH.

The bad flag signal BAD and the match flag signal MATCH are input to the conditional branching instruction changer BCC, and the conditional branching instruction changer BCC makes the bad flag signal BAD and the match flag signal MATCH valid at the time of a flag sense instruction (S95). As a result, the bad flag signal BAD and the match flag signal MATCH are input to the multiplexer MUX.

The multiplexer MUX can select one of the bad flag signal BAD and the match flag signal MATCH based on the flag sense selection signal MUT (S100). For example, if the flag sense selection signal MUT selects the bad flag signal BAD, the multiplexer MUX outputs the bad flag signal BAD to the pattern generator ALPG as the conditional branching instruction. As a result, the pattern generator ALPG can identify that the block under test is a bad block. The pattern generator ALPG changes the test pattern generation sequence so as to skip from the address information on the bad block to that on memory cells in the next block without performing the test on the bad block (S110). Namely, if the block under test is a bad block, the processing goes to the step S83, at which step the pattern generator ALPG increments the block address.

If the flag sense selection signal MUT selects the match flag signal MATCH, the multiplexer MUX outputs the match flag signal MATCH to the pattern generator ALPG as the conditional branching instruction. The pattern generator ALPG can thereby identify that the block under test is a bad block by the match flag signal MATCH similarly to the bad flag signal BAD. Accordingly, the pattern generator ALPG can execute the step S110 by the match flag signal MATCH similarly to the bad flag signal BAD. It is to be noted that a user may arbitrarily set the flag sense selection signal MUT. For example, the user may set the flag sense selection signal MUT to select one of the bad flag signal BAD and the match flag signal MATCH in every test cycle.

If the block address indicates the last block, the tester 100 finishes the test.

In the conventional tester, the bad block memory BBM instructs the waveform shaper FC to prohibit the write operation and instructs the logic comparator LC to prohibit the comparison operation but does not change the test pattern generation sequence. Due to this, the conventional tester accesses each page in the bad block. It is assumed, for example, that time for a write access once is t1 and time for reading once is t2. If one block includes 64 pages, it takes the conventional tester 64×(t1+t2) to access the bad block.

According to the embodiment of the present invention, by contrast, since the test pattern generation sequence output from the pattern generator ALPG is changed per se, it is possible to skip from the access to the bad block to the next block. Therefore, the tester 100 according to the embodiment can set access time for accessing the bad block to almost zero. In other words, the tester 100 can save the access time to the bad block, thereby making it possible to shorten the test time.

Note that the tester 100 is a tester-per-site that can generate discrete test patterns asynchronously for a plurality of MUTs, respectively. Now that the tester 100 is the tester-per-site, even if a good block test is performed on a certain MUT on which another test is performed in parallel, the tester 100 can skip from a bad block to the next block in the other MUT to perform a test on the next block.

1. A semiconductor tester for testing a memory under test including a block function capable of rewriting data in units of blocks including a plurality of pages, the plurality of pages including a plurality of bits stored in a plurality of memory cells, the semiconductor tester comprising:
a pattern generator generating address information on the pages and generating a test pattern;
a waveform shaper shaping the test pattern and outputting a test signal based on the shaped test pattern to the memory cells in the page identified by the address information;
a comparator comparing a result signal output from the memory under test receiving the test signal with an expectation value; and
a bad block memory storing information on a bad block in the memory under test in advance, when the page identified by the address information is included in the bad block, the bad block memory outputting a bad signal used to skip from the address information on the page included in the bad block to the address information on the page included in a next block under test.

2. The semiconductor tester according to claim 1, wherein
the bad block memory outputs an instruction to prohibit an output operation for outputting the test signal to the waveform shaper and outputs an instruction to prohibit a comparison operation for comparing the result signal with the expectation value to the comparator, when the memory cells identified by the address information are included in the bad block.

3. The semiconductor tester according to claim 1, further comprising:
a conditional branching instruction changer receiving a conditional branching instruction to change a generation pattern of the address information from the pattern generator, the conditional branching instruction changer changing the conditional branching instruction based on the bad signal.

4. The semiconductor tester according to claim 2, further comprising:
a conditional branching instruction changer receiving a conditional branching instruction to change a generation pattern of the address information from the pattern generator, the conditional branching instruction changer changing the conditional branching instruction based on the bad signal.

5. The semiconductor tester according to claim 1, wherein
the bad signal is output to the pattern generator as a conditional branching instruction to change a generation pattern of the address information, the generation pattern generated by the pattern generator.

6. The semiconductor tester according to claim 2, wherein
the bad signal is output to the pattern generator as a conditional branching instruction to change a generation pattern of the address information, the generation pattern generated by the pattern generator.

7. The semiconductor tester according to claim 3, wherein
the bad signal is output to the pattern generator as a conditional branching instruction to change a generation pattern of the address information, the generation pattern generated by the pattern generator.

8. The semiconductor tester according to claim 3, further comprising:
a matching detector comparing the result signal output from the memory under test with the expectation value and outputting a match signal indicating whether the result signal is matched or unmatched with the expectation value, wherein
the conditional branching instruction changer includes a multiplexer selecting one of the bad signal output from the bad block memory and the match signal output from the matching detector as the conditional branching instruction.

9. The semiconductor tester according to claim 5, further comprising:
a matching detector comparing the result signal output from the memory under test with the expectation value and outputting a match signal indicating whether the result signal is matched or unmatched with the expectation value, wherein
the conditional branching instruction changer includes a multiplexer selecting one of the bad signal output from the bad block memory and the match signal output from the matching detector as the conditional branching instruction.

10. A method of testing a memory under test using a semiconductor tester, the memory under test including a block function capable of rewriting data in units of blocks including a plurality of pages, the plurality of pages being a plurality of bits stored in a plurality of memory cells, wherein
the semiconductor tester includes: a pattern generator generating address information on the pages and generating a test pattern; a waveform shaper shaping the test pattern and outputting a test signal based on the shaped test pattern to the memory cells in the respective pages identified by the address information; a comparator comparing a result signal output from the memory under test receiving the test signal with an expectation value; and a bad block memory storing information on a bad block in the memory under test in advance, and wherein
the method comprises:
outputting a bad signal used to skip from the address information on the pages included in the bad block to the address information on the pages included in a next block under test, when the pages identified by the address information are included in the bad block.

11. The method according to claim 10, wherein
the bad block memory outputs an instruction to prohibit an output operation for outputting the test signal to the waveform shaper and outputs an instruction to prohibit a comparison operation for comparing the result signal with the expectation value to the comparator in the step of outputting the bad signal.

12. The method according to claim 10, further comprising:
outputting the bad signal to the pattern generator as a conditional branching instruction to change a generation pattern of the address information, the generation pattern generated by the pattern generator.

13. The method according to claim 11, further comprising:
outputting the bad signal to the pattern generator as a conditional branching instruction to change a generation pattern of the address information, the generation pattern generated by the pattern generator.
